(19) United States
(12) Patent Application Publication
(10) Pub. No.: US 2017/0165787 A1
(43) Pub. Date: Jun. 15, 2017

(54) MICROSTRUCTURE FORMING APPARATUS

(71) Applicant: Metal Industries Research and Development Centre, Kaohsiung (TW)

(72) Inventors: Chia-Ming JAN, Kaohsiung (TW); Cheng-Han HUNG, Kaohsiung (TW); Ying-Chieh LIN, Kaohsiung (TW)

(21) Appl. No.: 14/983,135

(22) Filed: Dec. 29, 2015

(30) Foreign Application Priority Data
Dec. 11, 2015 (TW) 104141627

(51) Int. Cl. B23K 26/06; H01L 21/268

(52) U.S. Cl. CPC B23K 26/0648; H01L 21/268; B23K 2203/56

(57) ABSTRACT

A microstructure forming apparatus is adapted for processing a workpiece and includes: a light source for emitting light toward the workpiece; a first axicon disposed between the light source and the workpiece; and a second axicon disposed between the first axicon and the workpiece. Light emitted from the light source forms a high-order Bessel beam after passing through the first axicon and the second axicon in sequence for processing and forming a microstructure in the workpiece.

### CROSS REFERENCE TO RELATED APPLICATION

This application claims priority of Taiwanese Application No. 104141627, filed on Dec. 11, 2015.

### FIELD

The disclosure relates to a microstructure forming apparatus, more particularly to a microstructure forming apparatus that is capable of generating a Bessel beam for forming a microstructure on a workpiece.

### BACKGROUND

Ultra-precision processing techniques are sufficient and mature to satisfy the processing demand and the precision requirement for manufacturing a microstructure with resolutions over 800 nanometers. However, current processing techniques for manufacturing a microstructure with resolutions below 800 nanometers generally adopts semiconductor manufacturing techniques, among which the dry etching procedure is most commonly used, but the processing time is rather long and the manufacturing parameters are specifically based on the characteristics of materials. Moreover, the semiconductor manufacturing techniques cannot produce the microstructures flexibly according to versatile design.

### SUMMARY

Therefore, an object of the disclosure is to provide a microstructure forming apparatus that can improve at least one of the drawbacks of the prior arts.

According to the disclosure, the microstructure forming apparatus is adapted for processing a workpiece and includes: a light source for emitting light toward the workpiece; a first axicon disposed between the light source and the workpiece; and a second axicon disposed between the first axicon and the workpiece. Light emitted from the light source forms a high-order Bessel beam after passing through the first axicon and the second axicon in sequence for processing and forming a microstructure in the workpiece.

### BRIEF DESCRIPTION OF THE DRAWINGS

Other features and advantages of the disclosure will become apparent in the following detailed description of the embodiment with reference to the accompanying drawings, of which:

FIG. 1 is a schematic diagram of the first embodiment of a microstructure forming apparatus according to the present invention;

FIG. 2 is a perspective view of a first axicon and a second axicon of the first embodiment;

FIG. 3 shows a microstructure formed by the first embodiment, the microstructure having a sub-micron scale;

FIG. 4 shows another microstructure formed by the first embodiment;

FIG. 5 is a schematic diagram of the second embodiment of a microstructure forming apparatus according to the present invention; and

FIG. 6 shows a microstructure formed by the second embodiment.

### DETAILED DESCRIPTION

Before the present invention is described in greater detail with reference to the accompanying preferred embodiments, it should be noted herein that like elements are denoted by the same reference numerals throughout the disclosure.

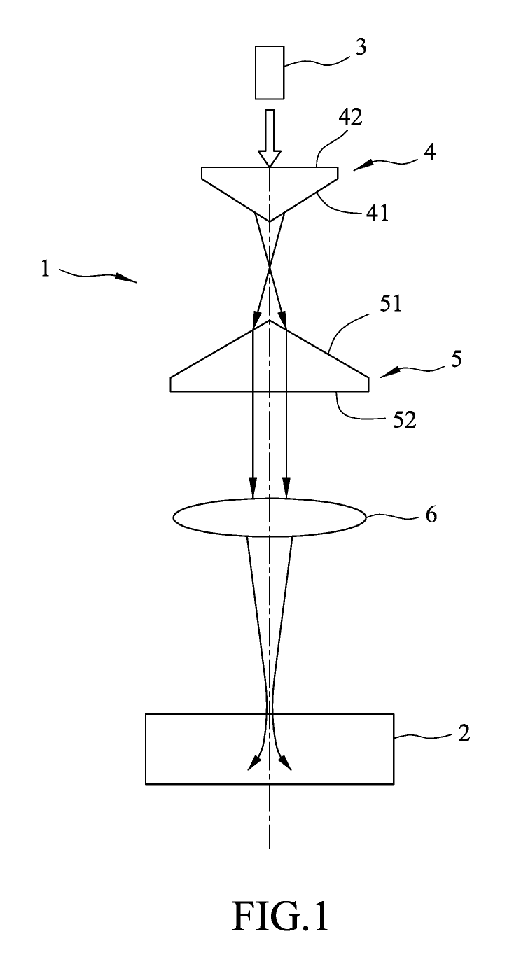

FIG. 1 shows the first embodiment of a microstructure forming apparatus 1 according to the present disclosure that is adapted for processing a workpiece 2. The microstructure forming apparatus 1 includes a light source 3, a first axicon 4, a second axicon 5, and an optical lens 6.

The light source 3 can be controlled in terms of light emission direction and beam shape, and is capable of emitting light toward the workpiece 2. The first axicon 4 is disposed between the light source 3 and the workpiece 2. The second axicon 5 is disposed between the first axicon 4 and the workpiece 2. The optical lens 6 is disposed between the second axicon 5 and the workpiece 2.

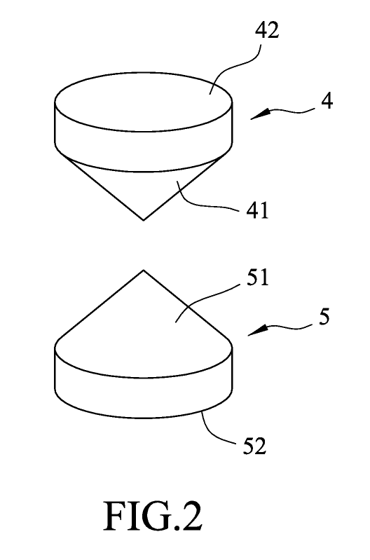

In this embodiment, the first axicon 4 and the second axicon 5 are each a conical-shape lens. As shown in FIG. 2, the first axicon 4 has a first convex conical surface 41 and a first planar surface 42 opposite to the first conical surface 41. The second axicon 5 has a second convex conical surface 51 and a second planar surface 52 opposite to the second conical surface 51. In this embodiment, the first planar surface 42 of the first axicon 4 faces the light source 3, the first and second conical surfaces 41, 51 face each other, and the second planar surface 52 of the second axicon 5 faces the optical lens 6.

In this embodiment, the light source 3 is a point light source, e.g., a laser diode. The first axicon 4, the second axicon 5 and the optical lens 6 are coaxially disposed. The sizes of the first and second axicon 4, 5 may change according to the required spot size of light emitting from the light source 3. The distance between the first and second axicon 4, 5 is adjustable according to the desired beam shape.

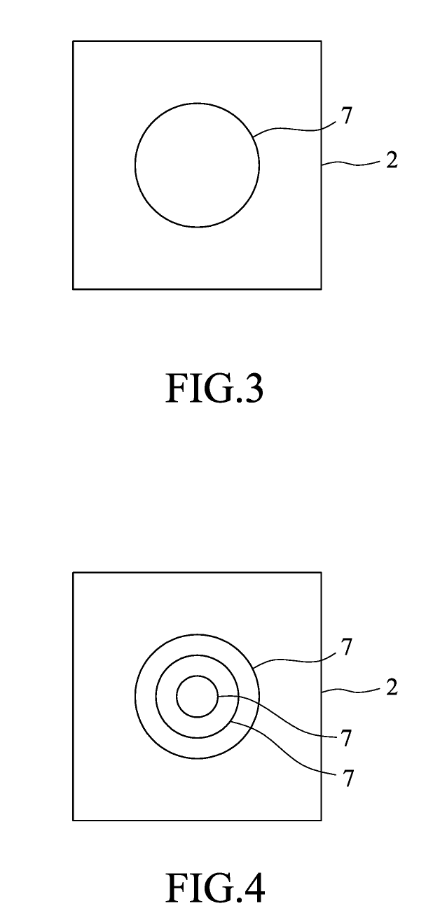

The light emitted from the light source 3 forms a Bessel beam after passing through the first planar surface 42 and the first conical surface 41 of the first axicon 4 in sequence, and is then further modulated into a ring-shaped high-order Bessel beam after passing through the second conical surface 51 and the second planar surface 52 of the second axicon 5 in sequence, thereby generating a highly directional electric field interference distribution. Thereafter, the ring-shaped high-order Bessel beam passes through the optical lens 6 and reaches the workpiece 2. The Bessel beam would cut the workpiece 2 so as to generate a indented annular (i.e., ring-like shape) microstructure 7 in the workpiece 2 (see FIG. 3). The characteristics of the optical lens 6 may adjust the size of the ring-shaped high-order Bessel beam. Through change of the distance between the optical lens 6 and the second axicon 5, the geometric size, such as the diameter, etc. of the annular microstructure 7 in the workpiece 2 can be adjusted. Therefore, modulation of the sizes is more convenient and flexible in this disclosure, and the microstructure 7 thus formed has a resolution below 500 nanometers. It is noted that a plurality of annular microstructures 7 that are concentrically disposed (see FIG. 4) can be formed by performing the aforesaid procedures multiple times. Before each time of performing the procedure, the distance between the optical lens 6 and the second axicon 5 is adjusted based on the desired size of the annular microstructure 7 to be formed.

It should be noted that, alignment calibration is preferably performed before forming the microstructure 7. To be specific, a spectroscope is disposed between the first axicon 4 and the second axicon 5, a resulted annular light is emitted toward the spectroscope and subsequently projected onto the first axicon 4 and the second axicon 5. The first axicon 4 and the second axicon 5 are determined to be coaxially disposed when the annular light projected onto the first axicon 4 aligns the annular light projected onto the second axicon 5. Then, the distance between the second axicon 5 and the optical lens 6 is adjusted according to the desired diameter scale of the annular microstructure 7 in the workpiece 2.

Through the arrangement of the light source 3, the first axicon 4 and the second axicon 5, a Bessel beam can be formed and processes the workpiece 2 so as to form the annular microstructure 7.

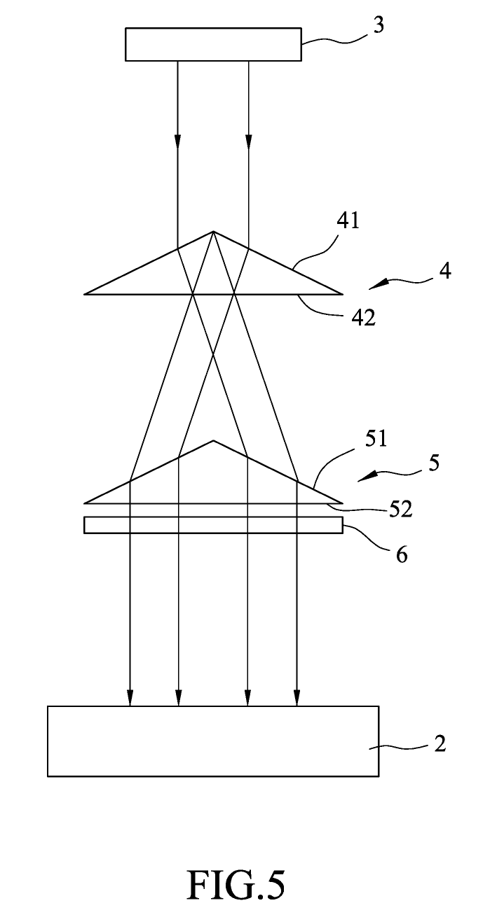

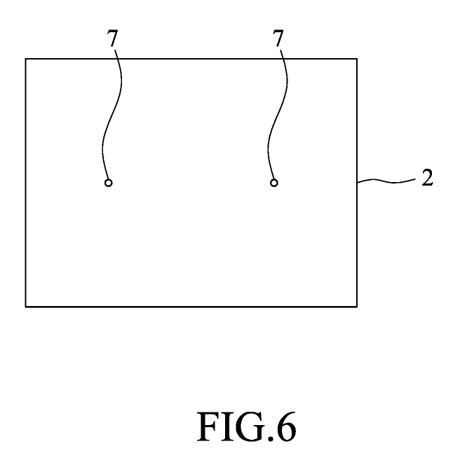

Referring to FIG. 5, the second embodiment of a microstructure forming apparatus 1 of this invention is shown to be similar to the first embodiment in structure, except that: the first conical surface 41 of the first axicon 4 faces the light source 3, and the first planar surface 42 faces the second conical surface 51 of the second axicon 5. In such co-axially arrangement, the light beam forms two Bessel beams after passing through the first axicon 4, the second axicon 5 and the optical lens 6 so as to generate two separated and indented dot-like microstructures 7 in the workpiece 2 (see FIG. 6). Particularly, in FIG. 5, a light beams e.g. Gaussian beam is emitted from the light source 2, and forms two Bessel beams, hence generating two dot-like microstructures 7 in the workpiece 2. At this moment, if relative displacement is performed between the microstructure forming apparatus 1 and the workpiece 2, the workpiece 2 is processed to have a linear or grid-shaped microstructure.

In this disclosure, the shape of the microstructure 7 can be adjusted through simple alteration of the arrangement of the first axicon 4.

It should be noted that, the optical lens 6 may be a convex lens or a concave lens. The convex lens could enlarge the shape of the high-order Bessel beam , and the concave lens could reduce the shape of the high-order Bessel beam. Therefore, the size of the high-order Bessel beam directed onto the workpiece 2 can be adjusted by alternating the optical lens 6.

To sum up, through the arrangement of the light source 3, the first axicon 4 and the second axicon 5, microstructures with a resolution below 500 nanometers can be obtained. The shape of the microstructures thus formed may be varied by altering the arrangement of the first axicon 4 and the second axicon 5. Moreover, though adjustment of the disposition and type of the optical lens 6, the geometric size of the microstructure can be altered. Therefore, the microstructure forming apparatus 1 of this disclosure is suitable for industrial application.

This disclosure is not limited to the disclosed exemplary embodiments but is intended to cover various arrangements included within the spirit and scope of the broadest interpretation so as to encompass all such modifications and equivalent arrangements.

What is claimed is:

1. A microstructure forming apparatus adapted for processing a workpiece, said microstructure forming apparatus comprising:
a light source for emitting light toward the workpiece;
a first axicon disposed between said light source and the workpiece; and
a second axicon disposed between said first axicon and the workpiece;
wherein light emitted from said light source forms a high-order Bessel beam after passing through said first axicon and said second axicon in sequence for processing and forming a microstructure in the workpiece.

2. The microstructure forming apparatus as claimed in claim 1, wherein said first axicon includes a first conical surface and a first planar surface opposite to said first conical surface and facing said light source, said second axicon including a second conical surface facing said first conical surface and a second planar surface opposite to said second conical surface and facing the workpiece.

3. The microstructure forming apparatus as claimed in claim 2, further comprising an optical lens disposed between said second axicon and the workpiece.

4. The microstructure forming apparatus as claimed in claim 1, wherein said light source is a point light source.

5. The microstructure forming apparatus as claimed in claim 1, wherein said first axicon includes a first conical surface facing said light source and a first planar surface opposite to said first conical surface, and said second axicon includes a second conical surface facing said first planar surface and a second planar surface opposite to said second conical surface and facing the workpiece.

6. The microstructure forming apparatus as claimed in claim 5, further comprising an optical lens disposed between said second axicon and the workpiece.
